(19) United States
(12) Patent Application Publication
(10) Pub. No.: US 2026/0196802 A1
(43) Pub. Date: Jul. 9, 2026

(54) ELECTRO-ABSORPTION MODULATED LASER (EML) DEVICE WITH FLARED MODULATOR

(71) Applicant: Applied Optoelectronics, Inc., Sugar Land, TX (US)

(72) Inventors: Dapeng XU, Houston, TX (US); XinXin Li, Sugar Land, TX (US); Huanlin Zhang, Sugar Land, TX (US)

(21) Appl. No.: 19/015,096

(22) Filed: Jan. 9, 2025

(51) Int. Cl. H01S 5/026; H01S 5/12; H01S 5/227; H01S 5/34

(52) U.S. Cl. CPC H01S 5/0265; H01S 5/12; H01S 5/227; H01S 5/34

(57) ABSTRACT

An electro-absorption modulated laser (EML) device has a flared modulator to improve modulation efficiency and transfer curve steepness of the EML device. The EML device generally includes a laser section, such as a distributed feedback (DFB) laser section, an electro-absorption modulator (EAM) section, and an isolation section between the laser section and EAM section. The EML device also includes an active region including a quantum well structure located in the laser section and the EAM section. A mesa section extends across the laser section, the isolation section, and the EAM section and is flared such that at least a portion of an isolation mesa section tapers outwardly and at least a portion of a modulator mesa section tapers inwardly. The EML device may be a ridge waveguide (RWG) type EML device or a buried heterostructure (BH) type EML device.

### TECHNICAL FIELD

The present disclosure relates to semiconductor lasers and more particularly, to an electro-absorption modulated laser (EML) device with a flared modulator.

### BACKGROUND INFORMATION

Semiconductor lasers may be used in optical communications and data processing applications (e.g., data centers). In optical communications, for example, the semiconductor laser may be used in a transmitter optical subassembly (TOSA) for transmitting optical signals. Electro-absorption modulated lasers (EMLs) may have advantages, for example, as compared to direct modulated lasers (DMLs) because of the relatively small chromatic dispersion of EMLs. Despite the advantages of an EML, the demand for ever-increasing speeds and frequencies in optical communications and data processing have created challenges with EMLs, particularly when operating at high power and/or high speed.

### SUMMARY

Consistent with an aspect of the present disclosure, an electro-absorption modulated laser (EML) device includes a laser section, an electro-absorption modulator (EAM) section, and an isolation section between the laser section and the EAM section. An active region is located in the laser section and the EAM section, wherein the active region includes a quantum well structure. A mesa section extends across the laser section, the isolation section, and the EAM section. The mesa section includes a laser mesa section in the laser section, an isolation mesa section in the isolation section, and an EAM mesa section in the EAM section. The EAM mesa section is flared such that at least a portion of the isolation mesa section tapers outwardly and at least a portion of the EAM mesa section tapers inwardly.

Consistent with a further aspect of the present disclosure, a buried heterostructure (BH) EML device includes a laser section, an electro-absorption modulator (EAM) section, and an isolation section between the laser section and the EAM section. A mesa section extends across the top of the laser section, the isolation section, and the EAM section. The mesa section includes a laser mesa section in the laser section, an isolation mesa section in the isolation section, and an EAM mesa section in the EAM section. The mesa section is flared such that at least a portion of the isolation mesa section tapers outwardly and at least a portion of the EAM mesa section tapers inwardly. An active region is located in both the laser section and the EAM section and is confined on both sides with a BH type configuration.

Consistent with another aspect of the present disclosure, a ridge-waveguide (RWG) EML device includes a laser section, an electro-absorption modulator (EAM) section, and an isolation section between the laser section and the EAM section. A mesa section extends across the top of the laser section, the isolation section, and the EAM section. The mesa section includes a laser mesa section in the laser section, an isolation mesa section in the isolation section, and an EAM mesa section in the EAM section. The mesa section is flared such that at least a portion of the isolation mesa section tapers outwardly and at least a portion of the EAM mesa section tapers inwardly. An active region is located in both the laser section and the EAM section and is below the mesa section with a RWG type configuration.

### BRIEF DESCRIPTION OF THE DRAWINGS

These and other features and advantages will be better understood by reading the following detailed description, taken together with the drawings wherein:

FIG. 1 is a schematic, perspective view of an electro-absorption modulate laser (EML) device with a flared modulator, consistent with embodiments of the present disclosure.

FIG. 2 is a schematic, side cross-sectional view of an EML device including a flared modulator, consistent with embodiments of the present disclosure.

FIG. 3 is a schematic, top view of an EML device with a flared modulator, consistent with embodiments of the present disclosure.

FIG. 4 is a graph illustrating the exponential decay of photocurrent density along an electro-absorption (EA) modulator cavity.

FIG. 5 is a schematic top view of one example of a flared modulator that may be used in an EML device, consistent with the present disclosure.

FIG. 6 is a graph illustrating power transmission in an EML device with the flared modulator shown in FIG. 5.

FIG. 7 is a graph illustrating refractive index in an EML device with the flared modulator shown in FIG. 5.

FIG. 8 is a graph illustrating mode profile in an EML device with the flared modulator shown in FIG. 5.

FIG. 9 is a graph illustrating optical confinement in an EML device with the flared modulator shown in FIG. 5.

FIG. 10 is a graph illustrating mode propagation in the XZ plane of an EML device with the flared modulator shown in FIG. 5.

### DETAILED DESCRIPTION

An electro-absorption modulated laser (EML) device, consistent with embodiments of the present disclosure, has a flared modulator to improve modulation efficiency and transfer curve steepness of the EML device. The EML device generally includes a laser section, such as a distributed feedback (DFB) laser section, an electro-absorption modulator (EAM) section, and an isolation section between the laser section and EAM section. The EML device also includes an active region including a quantum well structure located in the laser section and the EAM section. A mesa section extends across the laser section, the isolation section, and the EAM section and is flared such that at least a portion of an isolation mesa section tapers outwardly and at least a portion of a modulator mesa section tapers inwardly. The EML device may be a ridge waveguide (RWG) type EML device or a buried heterostructure (BH) type EML device.

A high extinction ratio (ER) and steep transfer curve is often desired for optical communications using an EML device. The ER represents the ratio of two optical power levels of a digital signal generated by an EML device, and the transfer curve represents EML output power as a function of the bias voltage. A steeper transfer curve may help to improve ER and reduce peak-to-peak modulation voltage (Vpp).

To achieve a high ER and steep transfer curve, an EML device may exploit the quantum-confined stark effect (QCSE) in a multiple quantum well (MQW) structure of the EAM section. The high power and/or high speed of an EML device, however, may push the limit of the QCSE. QCSE is the phenomenon where an applied electric field alters the absorption spectrum of a quantum well by shifting the energy levels of electrons and holes (i.e., carriers) within the quantum well, leading to a change in the light absorption characteristics, which can be used to modulate the optical signal by changing the applied voltage. The transport of carriers out of and into the wells has an influence on the speed of modulation in a quantum well EAM. At higher speed and/or higher power, however, carriers cannot completely escape out of the quantum well and thus pile up in the quantum well, which may significantly deteriorate the QCSE effects.

The total carrier lifetime is determined by two major carrier escape mechanisms-thermionic emission, where carriers with high energies cross a barrier of a quantum well and tunneling, where carriers having energies lower than the barrier energy cross the barrier by tunneling through it. In an InGaAsP material system, for example, a hole carrier may have difficulty escaping out and the lifetime of hole tunneling is much longer than that of thermionic emission. Barrier height (i.e., the energy difference between the bottom of a quantum well and the surrounding barrier material) has the most significant impact on carrier escape times.

The carrier lifetime in the quantum well is closely related to the concentration of photogenerated holes piled up in the quantum well. The two-dimensional photocarrier density may be expressed as:

$${n}_{2 D} = \frac{{J}_{ph} {τ}_{esc}}{q}$$

where Jₚₕ is the photocurrent density, τ_{esc} is the total carrier lifetime in the quantum well, and q is the electron charge. The photocurrent density Jₚₕ thus increases proportionally to the EAM optical output power. The adverse effects of carrier pile up in an EML device may include: electric field screening, which reduces the amount of QCSE energy shift within an electric field; saturating the QCSE modulation, which limits the incident optical intensity that can be tolerated; and photocarrier transport limited bandwidth.

Existing techniques to reduce carrier pile up in an EML device have included reducing the total carrier lifetime τ_{esc} and reducing the photocurrent density Jₚₕ, but these come with tradeoffs. Reducing the total carrier lifetime τ_{esc} (e.g., a shallow well) inhibits a steep transfer curve, particularly at higher operation voltages. Reducing the photocurrent density Jₚₕ reduces incident power, which lowers the EML optical power, and increases the mesa width of the modulator, which lowers RC bandwidth. A shorter EAM cavity (e.g., to provide higher modulation speeds/frequencies) and higher power create additional challenges for reducing carrier pile up and improving ER of an EML device.

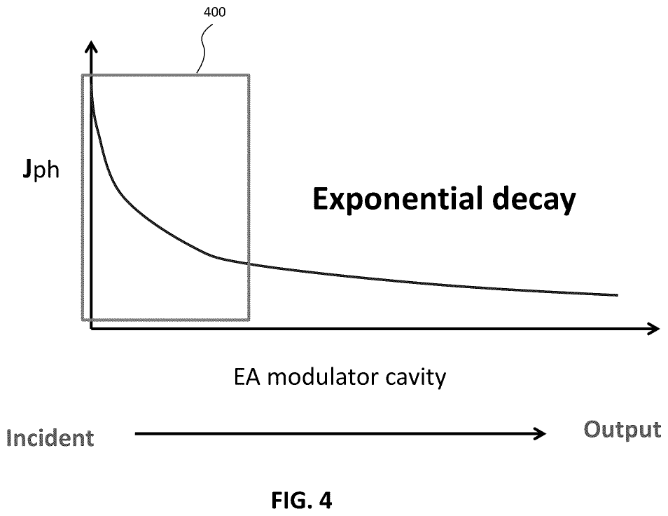

As shown in the plot of photocurrent density Jₚₕ along an EAM cavity in FIG. 4, a potential carrier pile up region 400 lies primarily in the few microns at the input side of the EAM cavity. A non-uniform mesa width that is flared at the input side of the EAM cavity may reduce the carrier pile up in this region and thus increases the steep transfer curve and lowers the peak-to-peak modulation voltage (Vpp). Such a design enables more freedom and tolerance for deep quantum well structures in the EAM.

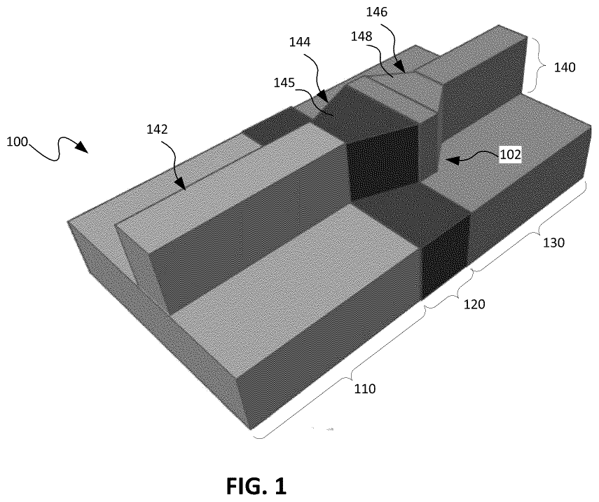

Referring to FIGS. 1-3, an EML device 100 with a flared modulator 102, consistent with embodiments of the present disclosure, is described in greater detail. The flared modulator 102 reduces photon current density at the input side, as mentioned above, which reduces carrier pile up in the quantum wells and thus avoids saturation of QCSE modulation and electric field screening effects. The EML device 100 with the flared modulator 102 may have a ridge waveguide (RWG) type configuration or a buried heterostructure (BH) type configuration, as known to those of ordinary skill in art.

The EML device 100 includes a laser section 110, an electro-absorption modulator (EAM) section 130, and an isolation section 120 between the laser section 110 and the EAM section 130. The EML device 100 also includes a mesa section 140 extending across the laser section 110, the isolation section 120, and the EAM section 130. In a semiconductor laser, the mesa is generally a raised region that acts as a waveguide to confine laser light within a specific area, thus defining the path and emission profile of the laser light. The mesa section 140 includes a laser mesa section 142, an isolation mesa section 144, and an EAM mesa section 146. The EAM mesa section 146 is flared such that at least a portion 145 of the isolation mesa section 144 tapers outwardly and at least a portion 148 of the EAM mesa section 146 tapers inwardly.

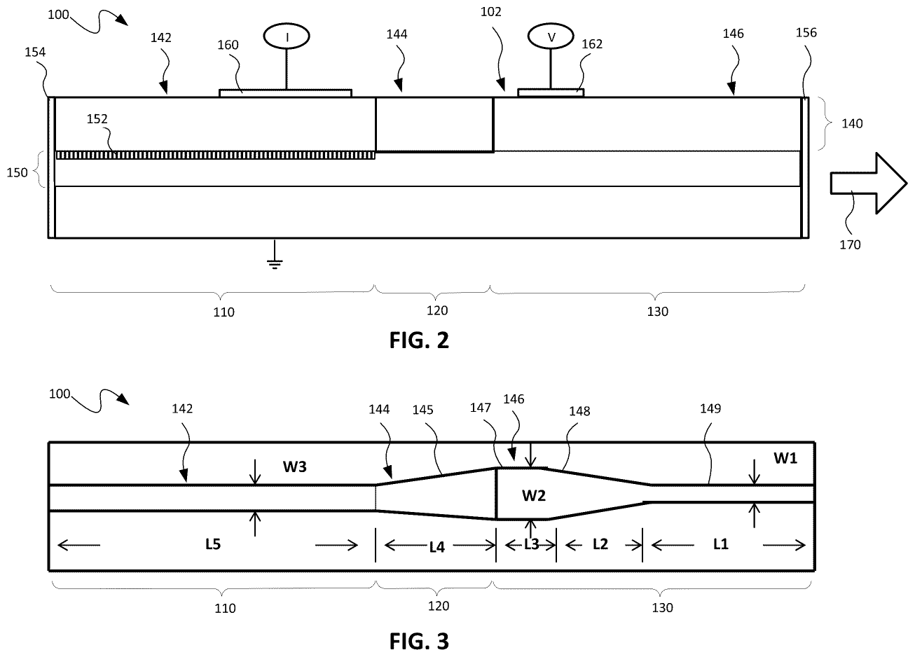

As shown in FIG. 2, the EML device 100 also includes an active region 150 located in at least the laser section 110 and the EAM section 130. The active region 150 includes a quantum well structure such as a multiple quantum well (MQW) structure. In a RWG type EML device, the active region 150 may be located below the mesa (also referred to as a ridge) that is formed by etching top cladding layers. In a RWG type EML device, a silica layer may be deposited to block the current flow so that the current enters only through the ridge and the cladding material used for the ridge may have a larger refractive index than the silica such that the mode index is higher under the ridge, which guides the optical mode in the lateral direction. In a BH type EML device, the active region 150 may be buried on all sides by several layers of lower refractive index, which allows strong mode confinement. The active region 150 and other layers in the EML device 100 may be configured and formed using materials and techniques known to those of ordinary skill in the art.

In this embodiment, the laser section 110 of the EML device 100 may include a distributed feedback (DFB) laser section including, for example, a DFB grating 152. The EML device 100 may include a highly reflective (HR) coating 154 at one end of the laser section 110 such that light is reflected internally and an anti-reflective (AR) coating 156 at an output end of the EAM section 130 such that light is allowed to exit. The HR coating 154 may include, for example, SiO2/TaOx. The AR coating 156 may include, for example, SiNOx.

The EML device 100 may include a laser contact 160 on the laser section 110 for receiving a laser bias current and a modulator contact 162 on the EAM section 130 for receiving a modulation voltage. The laser bias current causes laser light to be generated in the laser section 110 and the modulation voltage causes the laser light to be modulated in the EAM section 130. The modulated laser light 170 passes through the AR coating 156 and is output from the EML device 100.

In this embodiment of the EML device 100, as shown in FIG. 3, the EAM mesa section 146 includes a non-tapered portion 149 at the output end having a first width W1 and a first length L1. The inwardly-tapered portion 148 before the non-tapered portion 149 tapers from a second width W2 to the first width W1 over a second length L2. The EAM mesa section 146 may optionally include another non-tapered portion 147 before the inwardly-tapered portion 148, which has the second width W2 and a third length L3. The outwardly-tapered portion 145 of the isolation mesa section 144 tapers outwardly from a third width W3 to the second width W2 over a fourth length L4, and the laser mesa section 142 has the third width W3 and a fifth length L5. The second width W2 of the tapered portion 148 of the EAM mesa section 146 may be 1.5 to 5 times greater than the first width W1 of the non-tapered portion 149 and more specifically may be 2 to 4 times greater.

The transition from the outwardly-tapered portion 145 to the inwardly-tapered portion 148 may be designed to minimize propagation loss. Although the mesa width transition is shown as linear, this is not a limitation and the tapered portion 148 of the EAM mesa section 146 may have a non-linear transition.

The first length L1, second length L2, and third length L3 of the EAM mesa section 146 may be optimized by optical confinement, absorption and bandwidth. In some embodiments, the first length L1 may be in a range of 60 to 200 μm, the second length L2 may be in a range of 20 to 100 μm, and the third length L3 may be in a range of 0 to 20 μm, with a total modulator length (L1+L2+L3) in a range of 80 to 220 μm. The fourth length L4 of the isolation mesa section 144 may be in a range of 20 to 80 μm, and the fifth length L5 of the laser mesa section 142 may be in a range of 250 to 500 μm. The first width W1 may be in a range of 1 to 3 μm, the second width W2 may be in a range of 1.5 to 5 μm, and the third width W3 may be in a range of 1.5 to 2.5 μm.

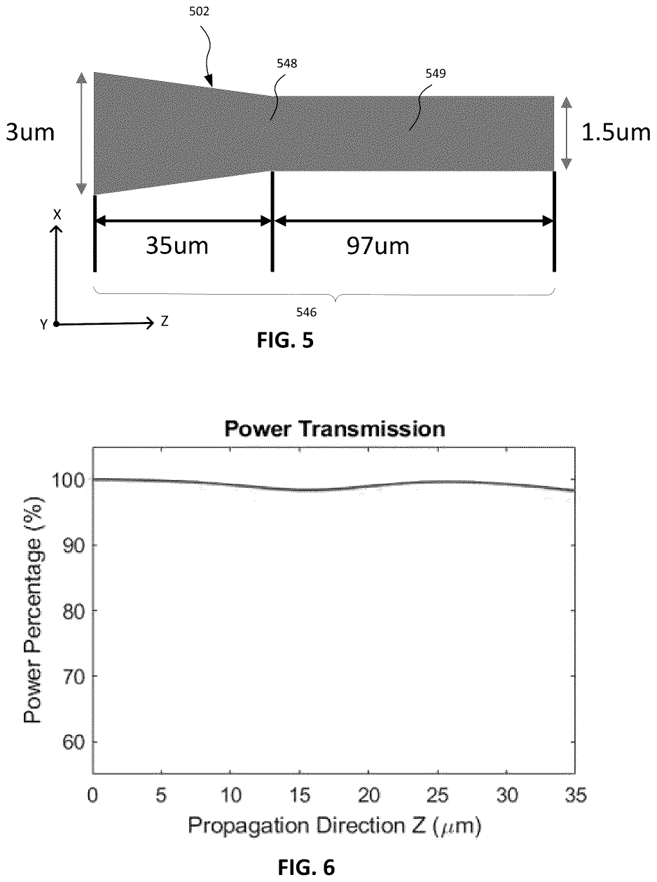

Referring to FIGS. 5-10, one example of a design for a flared modulator 502 is disclosed in greater detail. This design of the flared modulator 502 may be implemented in an EML device with a RWG configuration or a BH configuration, for example, as described above. FIG. 5 shows a schematic top view of the flared modulator 502 in an EAM section 546 of an EML device with the X axis extending along the width of the EAM section 546, the Z axis extending along the length of the EAM section 546, and the Y axis extending along the height of the EAM section 546. In this example, the flared modulator 502 includes a tapered portion 548 with a length L2 of 35 μm and a non-tapered portion 549 with a length L1 of 97 μm. The tapered portion 548 tapers from a second width W2 of 3 μm to a first width W1 of 1.5 μm.

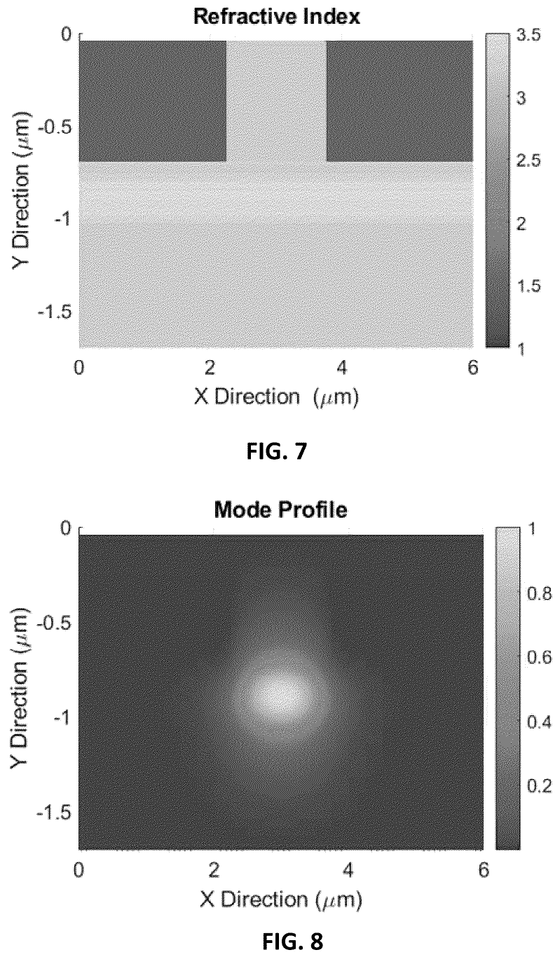

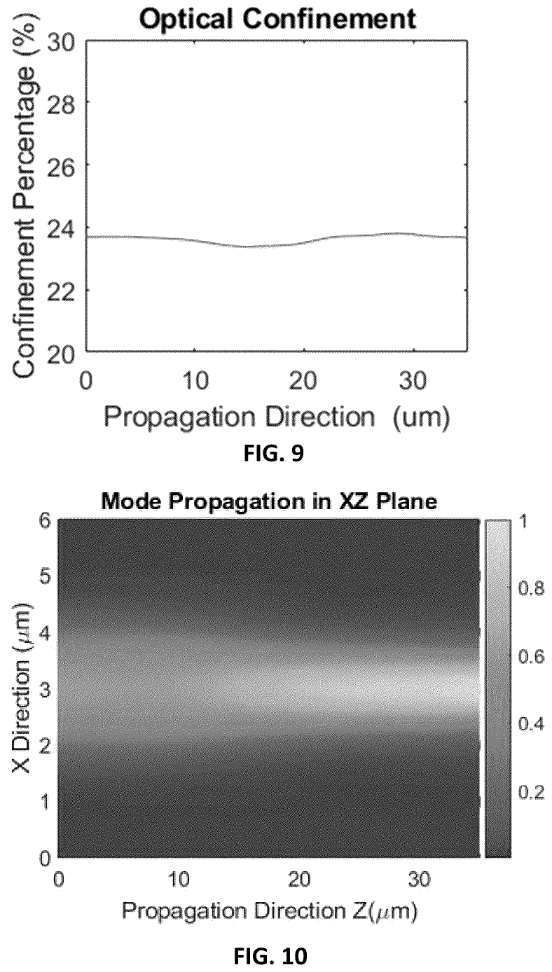

FIG. 6 shows the percentage of power transmission in a RWG type EML device including the flared modulator 502 along the propagation direction (e.g., along the Z axis) of the tapered portion 548. FIG. 7 shows the refractive index of a RWG type EML device with the flared modulator 502 along the X and Y directions. FIG. 8 shows the mode profile of a RWG type EML device with the flared modulator 502 along the X and Y directions. FIG. 9 shows the optical confinement percentage in a RWG type EML device with the flared modulator 502 along the propagation direction (e.g., along the Z axis) of the tapered portion 548. FIG. 10 shows the mode propagation in the XZ plane of an EML with the flared modulator 502 along the propagation direction of the tapered portion 548. This example of the flared modulator 502 provides adiabatic propagation with 98% of power transferred and a negligible change in optical confinement, e.g., as compared to a non-tapered modulator.

Accordingly, an EML device with a flared modulator, consistent with embodiments of the present disclosure, may improve the modulation efficiency and transfer curve steepness of an EML device with minimal propagation loss, even at higher speeds and/or higher power.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. An electro-absorption modulated laser (EML) device comprising:
a laser section;
an electro-absorption modulator (EAM) section;
an isolation section between the laser section and the EAM section;
an active region located in the laser section and the EAM section, wherein the active region includes a quantum well structure; and
a mesa section extending across the laser section, the isolation section, and the EAM section, wherein the mesa section includes a laser mesa section in the laser section, an isolation mesa section in the isolation section, and an EAM mesa section in the EAM section, and wherein the EAM mesa section is flared such that at least a portion of the isolation mesa section tapers outwardly and at least a portion of the EAM mesa section tapers inwardly.

2. The EML device of claim 1, further comprising a highly reflective (HR) coating at one end of the laser section and an anti-reflective (AR) coating at an output end of the EAM section.

3. The EML device of claim 1, wherein the laser section includes a distributed feedback (DFB) laser section.

4. The EML device of claim 1, wherein at least a portion of the EAM mesa section has a constant width before the EAM mesa section tapers inwardly.

5. The EML device of claim 1, wherein the EAM mesa section has a first width W1 proximate an output side of the laser and the EAM mesa section tapers from a second width W2 to the first width W1, and wherein the second width W2 is greater than the first width W1.

6. The EML device of claim 5, wherein the second width W2 is 1.5 to 5 times greater than the first width W1.

7. The EML device of claim 6, wherein the second width W2 is 2 to 4 times greater than the first width W1.

8. The EML device of claim 5, wherein at least a portion of the EAM mesa section has the second width W2 before the EAM mesa section tapers inwardly.

9. The EML device of claim 5, wherein the EAM mesa section tapers linearly from the second width W2 to the first width W1.

10. The EML device of claim 5, wherein the first width W1 is in the range of 1 to 3 μm and the second width W2 is in the range of 1.5 to 5 μm.

11. The EML device of claim 10, wherein the laser mesa section has a third width W3 in the range of 1.5 to 2.5 μm.

12. The EML device of claim 10, wherein the EAM mesa section with the first width W1 has a first length L1, the EAM mesa section that tapers has a second length L2, the EAM mesa section with the second width W2 has a third length L3, the isolation mesa section that tapers outwardly has a fourth length L4, and the laser mesa section has a fifth length L5.

13. The EML device of claim 12, wherein the first length L1 is in a range of 60 to 200 μm, the second length L2 is in a range of 20 to 100 μm, and the third length L3 is in a range of 0 to 20 μm.

14. The EML device of claim 13, wherein the fourth length L4 is in a range of 20 to 80 μm and the fifth length L5 is in a range of 250 to 500 μm.

15. The EML device of claim 1, wherein the EML device has a buried heterostructure (BH) configuration.

16. The EML device of claim 1, wherein the EML device has a ridge waveguide configuration.

17. A buried heterostructure (BH) EML device comprising:
a laser section;
an electro-absorption modulator (EAM) section;
an isolation section between the laser section and the EAM section;
a mesa section extending across the top of the laser section, the isolation section, and the EAM section, wherein the mesa section includes a laser mesa section in the laser section, an isolation mesa section in the isolation section, and an EAM mesa section in the EAM section, and wherein the mesa section is flared such that at least a portion of the isolation mesa section tapers outwardly and at least a portion of the EAM mesa section tapers inwardly; and
an active region located in both the laser section and the EAM section, wherein the active region is confined on both sides with a BH type configuration.

18. The BH EML device of claim 17, wherein at least a portion of the EAM mesa section has a constant width before the EAM mesa section tapers inwardly.

19. The BH EML device of claim 17, wherein the EAM mesa section has a first width W1 proximate an output side of the laser and the EAM mesa section tapers from a second width W2 to the first width W1, and wherein the second width W2 is 1.5 to 5 times greater than the first width W1.

20. A ridge-waveguide (RWG) EML device comprising
a laser section;
an electro-absorption modulator (EAM) section;
an isolation section between the laser section and the EAM section;
a mesa section extending across the top of the laser section, the isolation section, and the EAM section, wherein the mesa section includes a laser mesa section in the laser section, an isolation mesa section in the isolation section, and an EAM mesa section in the EAM section, and wherein the mesa section is flared such that at least a portion of the isolation mesa section tapers outwardly and at least a portion of the EAM mesa section tapers inwardly; and
an active region located in both the laser section and the EAM section, wherein the active region is below the mesa section with a RWG type configuration.

21. The RWG EML device of claim 20, wherein at least a portion of the EAM mesa section has a constant width before the EAM mesa section tapers inwardly.

22. The RWG EML device of claim 20, wherein the EAM mesa section has a first width W1 proximate an output side of the laser and the EAM mesa section tapers from a second width W2 to the first width W1, and wherein the second width W2 is 1.5 to 5 times greater than the first width W1.
